(19) United States
(12) Patent Application Publication
(10) Pub. No.: US 2022/0364219 A1
(43) Pub. Date: Nov. 17, 2022

(54) LaCoO3 THIN FILM DEPOSITION BY DC METAL CO-SPUTTERING

(71) Applicant: NORTHROP GRUMMAN SYSTEMS CORPORATION, Falls Church, VA (US)

(72) Inventors: Rajashree Bhattacharya, San Jose, CA (US); Vincent Gambin, Rancho Palos Verdes, CA (US)

(21) Appl. No.: 17/318,519

(22) Filed: May 12, 2021

(51) Int. Cl. C23C 14/08; C23C 14/58

(52) U.S. Cl. CPC C23C 14/08; C23C 14/5806

(57) ABSTRACT

A method for producing a LaCoO₃ film on a substrate that includes positioning the substrate in a vacuum chamber, positioning a cobalt target in the vacuum chamber, positioning a lanthanum target in the vacuum chamber, providing oxygen in the vacuum chamber, and sputtering cobalt atoms off of the cobalt target and lanthanum atoms off of the lanthanum target so that the cobalt and lanthanum atoms interact with the oxygen to form the LaCoO₃ film on the substrate. A power limiter that employs one or more LaCoO₃ films is also disclosed.

### BACKGROUND

### Field

This disclosure relates generally to a method for producing a LaCoO₃ film on a substrate and, more particularly, to a method for producing a LaCoO₃ film on a substrate that includes sputtering cobalt and lanthanum atoms from two metal targets that react with oxygen in a high vacuum sputtering chamber to create the LaCoO₃ film.

### Discussion of the Related Art

RF power limiters are often employed in receiver front end circuits and other devices to protect sensitive electrical components, such as low noise amplifiers (LNA), from high power RF signals. Traditionally these power limiters are solid-state devices that employ semiconductor components, such as p-i-n diodes or MESFET devices, that limit input power for a certain frequency range. However, with the advance of power and agility in RF components and systems additional challenges in the form of low power consumption, higher incident power control and high reliability are placed on traditional RF power limiters. These challenges have led to the investigation of new power limiting materials that often employ an insulator-to-metal phase transition (IMT) in response to a certain temperature change that improve with increasing power. In response to increasing current, and thus temperature, an IMT material will transition from an insulative state to a metallic state, which shunts power above a given threshold.

One IMT material that can demonstrate IMT behavior for power limiting purposes is vanadium dioxide (VO₂). VO₂ has been synthesized by a wide variety of methods, such as molecular beam epitaxy (MBE), pulsed laser deposition and direct current and radio frequency sputtering. VO₂ provides a sharp drop in resistance as the material heats to around 340 degrees Kelvin. However, this temperature is generally too low for practical device operation for many systems.

Another IMT material that can demonstrate IMT behavior is lanthanum cobalt oxide (LaCoO₃). LaCoO₃ has an IMT at a higher temperature than other IMT materials such as VO₂. More particularly, LaCoO₃ exhibits a large reduction in resistivity at around 500 degrees Kelvin as a result of a non-structural phase transition, such as electronic spin state transition or orbital melting mechanism, that provides a rapid electrical resistivity drop as a function of increasing temperature. Typical methods of synthesis for LaCoO₃ found in the literature focus on the production of porous volumes because the majority of research on the material is in its application for catalysis for gas sensors and humidity sensors. Various processes have been reported in the literature for depositing thin films of LaCoO₃ that typically focus on catalytic applications, which include MBE, ion beam sputtering, chemical vapor deposition and pulsed laser deposition. MBE is known to produce high quality, smooth, crystalline films. However, it is a slow, difficult and an expensive process. The literature shows that films of LaCoO₃ can be produced using DC co-sputtering of metal targets, but those processes required post-deposition calcination steps to properly oxygenate and crystallize the films.

### BRIEF DESCRIPTION OF THE DRAWINGS

FIG. 1 is a schematic block diagram of a power limiter employing a LaCoO₃ film; and

FIG. 2 is a schematic block diagram of a sputtering system for producing a LaCoO₃ film.

### DETAILED DESCRIPTION OF THE EMBODIMENTS

The following discussion of the embodiments of the disclosure directed to a method for producing a LaCoO₃ film on a substrate is merely exemplary in nature, and is in no way intended to limit the disclosure or its applications or uses.

This disclosure proposes producing RF devices that employ a LaCoO₃ film that provide a quick drop in resistance as temperature increases above a threshold. The challenge is to produce smooth, high quality crystalline thin LaCoO₃ films having a high insulator-to-metal transition point on various substrates that is relatively low cost, amenable to large scale production. It should also consist of only one step for simplicity and to protect underlying device layers from damage in high temperature calcination. The process will be able to deposit the LaCoO₃ films onto a variety of substrates with varying dielectric properties in order to optimize the film properties and device performance.

In order to provide an RF device as described above, this disclosure describes a single step DC sputtering process for synthesis of LaCoO₃ using relatively cheap source materials that can quickly produce large wafer scale material. Rather than use a ceramic target of pre-sintered LaCoO₃, the proposed process utilizes cheaper metal targets of lanthanum and cobalt. The process uses a heated substrate in conjunction with deposition of the metal targets in a reactive oxygen/argon atmosphere. These metals are vaporized by a direct current magnetron gun that ejects material toward the substrate. Under these conditions, the metals react and crystallize directly onto the substrate surface to form the LaCoO₃ film. Thus, no secondary processing steps are required to fully crystallize or oxygenate the film. An additional advantage of the proposed process is that using independently controlled metal targets allows for tuning of the composition of the film, affording greater control over optimization of the film properties. The ability to vary the substrate temperature with this process also allows for balancing the benefits between highly crystalline films grown at 700° C. and the amorphous films grown at low temperatures. Furthermore, while still able to produce smooth, quality films, sputtering is considered a low cost and fast production tool used for large wafer scale synthesis.

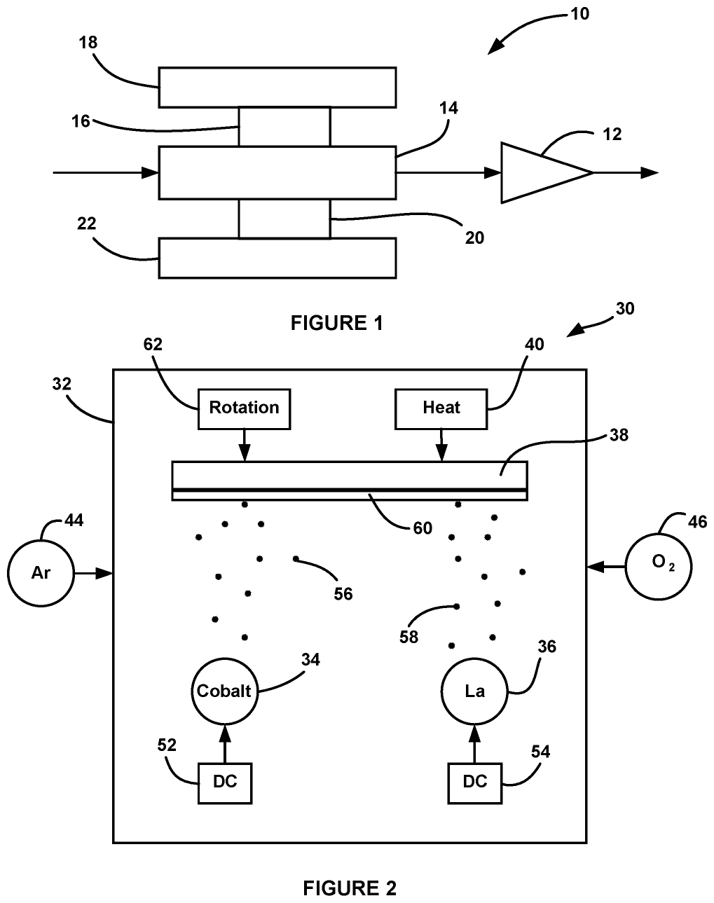

FIG. 1 is a schematic block diagram of a power limiter 10 that limits the amount of power that can be delivered to a sensitive electrical device 12, such as an LNA. An input signal is provided to a waveguide 14 that delivers the signal to the device 12. An LaCoO₃ film 16 is formed on one side of the waveguide 14 and is coupled to a grounded element 18 and an LaCoO₃ film 20 is formed on an opposite side of the waveguide 14 and is coupled to a grounded element 22. As the power of the input signal increases more heat is generated in the films 16 and 20. When the heat level in the films 16 and 20 is below a certain threshold, the films 16 and 20 are an insulator and the signal propagates straight through the waveguide 14 to the device 12. When the heat level in the films 16 and 20 reaches the threshold, the films 16 and 20 transition to a metal and become conductive, and power in the signal is shunted through the films 16 and 20 to the grounded elements 18 and 22, and minimal power is transmitted to the device 12. When the heat level in the films 16 and 20 falls below the threshold, the films 16 and 20 transition back to an insulator.

FIG. 2 is a schematic block diagram of a sputter system 30 including a vacuum chamber 32. A cobalt source target 34 and a lanthanum source target 36 are positioned with the chamber 32 relative to a substrate 38, where the substrate 38 is intended to represent any substrate of a suitable material, such as silicon carbide, sapphire, fused silica, silicon, lanthanum aluminate, etc., or a fully fabricated device, such as a GaN wafer. Depending on the application, the substrate 38 may be heated by a heater 40 to a desired temperature, for example, between 400° C. and 700° C. to enhance the sputtering process. An argon or other suitable inert gas from a source 44 and oxygen from a source 46 are emitted into the chamber 32, which increases the pressure in the chamber 32 to, for example, 5 mtorr.

A negative bias potential is applied to the targets 34 and 36 by DC sources 52 and 54, respectively. Magnets (not shown) are employed to increase the ionization frequency by trapping a cloud of electrons near the surface of the targets 34 and 36, which increases the likelihood of collision and ionization of the argon gas. Positive argon ions bombard the targets 34 and 36, which releases cobalt atoms 56 from the target 34 and lanthanum atoms 58 from the target 36. The atoms 56 and 58 are drawn to the substrate 38 where they react directly with the oxygen to create a crystalized LaCoO₃ film 60 on the substrate 38. A rotation device 62 rotates the substrate 38 so that the film 60 has a uniform concentration of cobalt and lanthanum. The sputtering process is continued until the thickness of the film 60 reaches a desired thickness, for example, 40-200 nm. The percentage of oxygen in the chamber 32 is carefully tuned to avoid significant oxidization of the targets 34 and 36.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

1. A method for producing a LaCoO₃ film on a substrate, said method comprising:
positioning the substrate in a vacuum chamber;
positioning metal a cobalt target in the vacuum chamber;
positioning a metal lanthanum target in the vacuum chamber;
providing oxygen in the vacuum chamber;
sputtering cobalt atoms off of the cobalt target and lanthanum atoms off of the lanthanum target so that the cobalt and lanthanum atoms interact with the oxygen to form the LaCoO₃ film on the substrate; and
heating the substrate while the LaCoO₃film is being formed.

2. (canceled)

3. The method according to claim 1 wherein heating the substrate includes heating the substrate to a temperature between 400° C. and 700° C.

4. The method according to claim 1 further comprising rotating the substrate.

5. The method according to claim 1 wherein sputtering cobalt and lanthanum atoms includes generating an inert gas plasma in the vacuum chamber and electrically biasing the cobalt and lanthanum targets so that plasma ions from the plasma bombard the cobalt and lanthanum targets.

6. The method according to claim 5 wherein the inert gas is argon.

7. The method according to claim 1 wherein the substrate is part of a power limiter.

8. A system for producing a LaCoO₃ film on a substrate, said system comprising:
means for positioning the substrate in a vacuum chamber;
means for positioning a metal cobalt target in the vacuum chamber;
means for positioning a metal lanthanum target in the vacuum chamber;
means for providing oxygen in the vacuum chamber;
means for sputtering cobalt atoms off of the cobalt target and lanthanum atoms off of the lanthanum target so that the cobalt and lanthanum atoms interact with the oxygen to form the LaCoO₃ film on the substrate; and
means for heating the substrate while the LaCoO₃ film is being formed.

9. (canceled)

10. The system according to claim 8 wherein the means for heating the substrate heats the substrate to a temperature between 400° C. and 700° C.

11. The system according to claim 8 further comprising means for rotating the substrate.

12. The system according to claim 8 wherein the means for sputtering cobalt and lanthanum atoms generates an inert gas plasma in the vacuum chamber and electrically biases the cobalt and lanthanum targets so that plasma ions from the plasma bombard the cobalt and lanthanum targets.

13. The system according to claim 12 wherein the inert gas is argon.

14. The system according to claim 8 wherein the substrate is part of a power limiter.

15. A power limiter for limiting power applied to an electronic device, said power limiter comprising:
a waveguide that receives an input signal to be sent to the electronic device;
at least one LaCoO₃ film formed to the waveguide; and
at least one grounded element formed to the at least one LaCoO₃ film opposite to the waveguide, wherein when the heat level in the at least one LaCoO₃ film is below a predetermined threshold, the at least one LaCoO₃ film is an insulator and the input signal propagates straight through the waveguide to the electronic device 12, and wherein when the heat level in the at least one LaCoO₃ film reaches the threshold, the at least one LaCoO₃ film becomes conductive, and the input signal is shunted through the at least one LaCoO₃ film to the at least one grounded element.

16. The power limiter according to claim 15 wherein the at least one LaCoO₃ film is a first LaCoO₃ film formed to one side of the waveguide and a second LaCoO₃ film formed to an opposite side of the waveguide, and wherein the at least one grounded element is a first grounded element formed to the first LaCoO₃ film and a second grounded element formed to the second LaCoO₃film.

17. The power limiter according to claim 15 wherein the at least one LaCoO₃ film has a thickness between 40 and 200 nm.

18. The method according to claim 1 wherein the LaCoO₃ film is formed on the substrate to a thickness in the range of 40-200 nm.

19. The system according to claim 8 wherein the LaCoO₃ film is formed on the substrate to a thickness in the range of 40-200 nm.
